(19) United States
(12) Patent Application Publication
(10) Pub. No.: US 2013/0014795 A1
(43) Pub. Date: Jan. 17, 2013

(54) THERMOELECTRIC MODULE

(71) Applicants: Ju Hwan YANG, Gyeonggi-do (KR); Dong Hyeok CHOI, Gyeonggi-do (KR); Sung Ho LEE, Gyeonggi-do (KR); Sung Kwon WI, Seoul (KR)

(72) Inventors: Ju Hwan YANG, Gyeonggi-do (KR); Dong Hyeok CHOI, Gyeonggi-do (KR); Sung Ho LEE, Gyeonggi-do (KR); Sung Kwon WI, Seoul (KR)

(73) Assignee: SAMSUNG ELECTRO-MECHANICS CO., LTD., Suwon (KR)

(21) Appl. No.: 13/473,209

(22) Filed: May 16, 2012

(30) Foreign Application Priority Data
Jul. 15, 2011 (KR) 10-2011-0070564

(51) Int. Cl. H01L 35/28

(52) U.S. Cl. 136/200

(57) ABSTRACT

Disclosed herein is a thermoelectric module. The thermoelectric module includes: an upper substrate and a lower substrate each having a plurality of grooves formed on one surface thereof; a plurality of heat radiation pads embedded in the plurality of grooves; a plurality of electrodes formed on surfaces of the plurality of heat radiation pads and corresponding to the plurality of heat radiation pads one by one; and thermoelectric elements including p-type elements and n-type elements and electrically connected to the plurality of electrodes. According to the present invention, the heat radiation pads are embedded in the respective grooves formed on the upper substrate and the lower substrate, thereby maximizing heat transfer efficiency, and functioning as an insulator for preventing an electric short between the substrates and the electrodes.

### CROSS REFERENCE(S) TO RELATED APPLICATIONS

This application claims the benefit under 35 U.S.C. Section 119 of Korean Patent Application Serial No. 10-2011-0070564, entitled “Thermoelectric Module” filed on Jul. 15, 2011, which is hereby incorporated by reference in its entirety into this application.

### BACKGROUND OF THE INVENTION

1. Technical Field

The present invention relates to a thermoelectric module, and more particularly, to a thermoelectric module including a heat radiation pad.

2. Description of the Related Art

Due to the rapid increase in the use of fossil energy, which causes global warming and energy depletion, there is a growing interest in a thermoelectric module.

The thermoelectric module is utilized as a cooling member, by substituting for Freon gas, which is a substance causing air pollution, and is also widely used as a small electric generator using a Seebeck effect.

As for the thermoelectric module, when current flows through a loop, which is formed by grounding metals to each other using a thermoelectric element, an electric potential difference is generated due to a difference of Fermi energy, and thus, electrons move from one metal to the other metal with a necessary energy, which causes absorption of heat or cooling.

Whereas, the other metal releases a heat energy having such an energy level as the energy brought by the electrons, which causes radiation of heat. This is referred to as Peltier effect, and is an operation principle of a cooling apparatus by the thermoelectric element.

Here, positions of heat absorption and heat radiation are determined depending on the kind of semiconductor and the direction in which current flows, and effects thereof also are different from each other due to difference in the materials.

FIG. 1 is a schematic cross-sectional view of a thermoelectric module having a general structure.

As for a general thermoelectric module 10, an N-type thermoelectric element 11 and a P-type thermoelectric element 12 are electrically connected by electrodes 3 and 6. Here, when direct current is applied to the thermoelectric module 10, heat absorption occurs at an upper substrate 13 and heat radiation occurs at a lower substrate 14. In this case, as described above, the positions of heat absorption and heat radiation may be changed depending on the direction of current.

Meanwhile, the upper substrate 13 and the lower substrate 14 need to have high thermal conductivity and have heat insulation property in order to maximize heat transfer efficiency.

### SUMMARY OF THE INVENTION

An object of the present invention is to provide a thermoelectric module having a member for improving heat transfer efficiency.

According to an exemplary embodiment of the present invention, there is provided a thermoelectric module, including: an upper substrate and a lower substrate each having a plurality of grooves formed on one surface thereof; a plurality of heat radiation pads embedded in the plurality of grooves; a plurality of electrodes formed on surfaces of the plurality of heat radiation pads and corresponding to the plurality of heat radiation pads one by one; and thermoelectric elements including a p-type element and an n-type element and electrically connected to the plurality of electrodes.

According to an exemplary embodiment of the present invention, there is provided a thermoelectric module, including: an upper substrate having first grooved formed on a lower surface thereof; a lower substrate having second grooves formed on an upper surface thereof facing the upper substrate; first and second heat radiation pads respectively embedded in the first and second grooves of the upper and lower substrates; first and second electrodes formed correspondingly to the first and second heat radiation pads one by one, the first and second electrodes guiding flow of electric power when the electric power is applied to the thermoelectric module; and thermoelectric elements formed between the first and second electrodes facing each other.

### BRIEF DESCRIPTION OF THE DRAWINGS

FIG. 1 is a cross-sectional view of a general thermoelectric module; and

FIG. 2 is a cross-sectional view of a thermoelectric module according to an exemplary embodiment of the present invention.

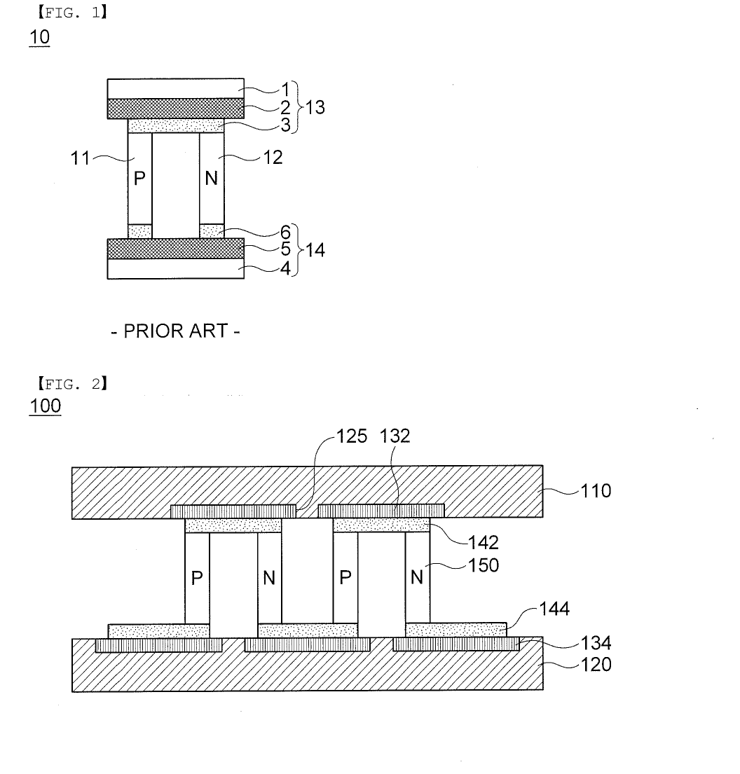

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

Further, when it is determined that the detailed description of the known art related to the present invention may obscure the gist of the present invention, the detailed description thereof will be omitted. Further, the following terminologies are defined in consideration of the functions in the present invention and may be construed in different ways by the intention of users and operators. Therefore, the definitions thereof should be construed based on the contents throughout the specification.

The technical idea of the present invention is determined by the claims and the exemplary embodiments herein are provided so that the technical idea of the present invention will be efficiently explained to those skilled in the art to which the present invention pertains.

Hereinafter, a thermoelectric module according to exemplary embodiments of the present invention will be described with reference to the accompanying drawings.

FIG. 2 is a cross-sectional view of a thermoelectric module according to an exemplary embodiment of the present invention.

As shown in FIG. 2, a thermoelectric module 100 according to the present invention includes substrates 110 and 120, heat radiation pads 132 and 134, electrodes 142 and 144, and thermoelectric elements 150.

The substrates 110 and 120 are divided into an upper substrate 110 and a lower substrate 120, and these upper substrate 110 and lower substrate 120 form external appearances of upper and lower surfaces.

The upper substrate 110 and the lower substrate 120 are made of a material having high thermal conductivity, which enable an exothermic reaction or an endothermic reaction to occur when electric power is applied to the thermoelectric module 100. For example, the upper substrate 110 and the lower substrate 120 may be formed of any one conductive metal of copper (Cu), aluminum (Al), and alumina.

A plurality of grooves 125 may be formed on a lower surface of the upper substrate 110 and an upper surface of the lower substrate 120 at a predetermined space. Here, the grooves 125 may be formed through a wet or dry etching process.

The grooves 125 according to the present invention are used as spaces in which heat radiation pads 132 and 134 to be described are embedded.

When the upper substrate 110 and the lower substrate 120 each have a thickness of, for example, 100 μm, the groove may have a depth of, for example, 10 μm.

As such, the heat radiation pads 132 and 134 are embedded in the respective grooves 125 formed on the upper substrate 110 and the lower substrate 120 each, and thus, heat transfer efficiency can be maximized. They also may be used as an insulator for preventing electric short between the substrates 110 and 120 and the electrodes 142 and 144.

The heat radiation pads may include upper heat radiation pads 132 formed in the grooves formed on the lower surface of the upper substrate 110 and lower heat radiation pads 134 formed in the grooves formed on the upper surface of the lower substrate 120.

The heat radiation pads 132 and 134 may be made of, for example, a polymer resin. The polymer resin in the present invention is formed by dispersing thermal conductive filler in a silicon resin.

More specifically, the heat radiation pads 132 and 134 may be formed as a paste for heat radiation, by combining one thermal conductive filler of alumina having high heat conductivity, silicon nitride (SiNx), and aluminum nitride (AlN), with gelled siloxane polymer.

These heat radiation pads 132 and 134 may be completed by using a screen printing method and a dry method.

The electrodes 142 and 144 may guide flow of electric power when electric power is applied to the thermoelectric module 100.

The electrodes 142 and 144 may be formed of, for example, copper (Cu), which is a conductive metal having high electric conductivity, and the electrodes 142 and 144 may have a thickness of, for example, 100 μm.

The electrodes 142 and 144 may include upper electrodes 142 contacted with the lower surface of the upper substrate 110 and lower electrodes 144 contacted with the upper surface of the lower substrate 120.

More specifically, the upper electrodes 142 may be formed to correspond to the upper heat radiation pads 132 formed in the grooves of the upper substrate 110 one by one, and the lower electrodes 144 may be formed to correspond to the lower heat radiation pads 134 formed in the grooves of the lower substrate 120 one by one.

Here, a long side length of the upper electrode 142 and the lower electrode 144 each, for example, may be smaller than a long side length of the corresponding heat radiation pads 132 and 134 each.

As such, the electrodes 142 and 144 are spaced from the heat radiation pads 132 and 134 at a predetermined space, by making the long side length of each of the electrodes 142 and 144 smaller than the long side length of each of the heat radiation pads 132 and 134, thereby preventing an electric short between the electrodes 142 and 144 and the substrates 110 and 120.

The thermoelectric elements 150 are electrically connected to the electrodes 142 and 144. When direct current is applied to the electrodes 142 and 144, heat radiation occurs at the upper substrate 110 and heat absorption occurs at the lower substrate 120. However, heat radiation may occur at the lower substrate 120 and heat absorption may occur at the upper substrate 110, without the limitation of the exemplary embodiment of the present invention.

These thermoelectric elements 150 may include a P-type thermoelectric element (P) and an N-type thermoelectric element (N).

As such, in the thermoelectric module 100 according to the present invention, the heat radiation pads 132 and 134 are embedded in the respective grooves 125 formed on the upper substrate 110 and the lower substrate 120 each, and thus, heat transfer efficiency can be maximized. The radiation pads 132 and 134 can also be used as an insulator for preventing electric short between the substrates 110 and 120 and the electrodes 142 and 144.

As set forth above, according to the exemplary embodiment of the present invention, the heat radiation pads are embedded in the respective grooves formed on the upper substrate and the lower substrate, thereby maximizing heat transfer efficiency, and functioning as an insulator for preventing an electric short between the substrates and the electrodes.

While the present invention has been shown and described in connection with the embodiments, it will be apparent to those skilled in the art that modifications and variations can be made without departing from the spirit and scope of the invention as defined by the appended claims.

What is claimed is:

1. A thermoelectric module, comprising:
an upper substrate and a lower substrate each having a plurality of grooves formed on one surface thereof;
a plurality of heat radiation pads embedded in the plurality of grooves;
a plurality of electrodes formed on surfaces of the plurality of heat radiation pads and corresponding to the plurality of heat radiation pads one by one; and
thermoelectric elements including p-type elements and n-type elements and electrically connected to the plurality of electrodes.

2. The thermoelectric module according to claim 1, wherein the upper substrate and the lower substrate each have a thickness of 100 μm.

3. The thermoelectric module according to claim 2, wherein the plurality of grooves each have a depth of 10 μm.

4. The thermoelectric module according to claim 1, wherein a long side length of the heat radiation pad is longer than a long side length of the electrode.

5. The thermoelectric module according to claim 1, wherein the heat radiation pad is formed of a polymer resin.

6. The thermoelectric module according to claim 1, wherein the polymer resin is formed into a paste for heat radiation, by combining one thermal conductive filler of alumina, silicon nitride (SiNx) and aluminum nitride (AlN) with gelled siloxane polymer.

7. A thermoelectric module, comprising:
an upper substrate having first grooves formed on a lower surface thereof;
a lower substrate having second grooves formed on an upper surface thereof facing the upper substrate;
first and second heat radiation pads respectively embedded in the first and second grooves of the upper and lower substrates;
first and second electrodes formed correspondingly to the first and second heat radiation pads one by one, the first and second electrodes guiding flow of electric power when the electric power is applied to the thermoelectric module; and
thermoelectric elements formed between the first and second electrodes facing each other.

8. The thermoelectric module according to claim 7, wherein a long side length of each of the first and second heat radiation pads is longer than a long side length of each of the first and second electrodes.

9. The thermoelectric module according to claim 7, wherein the first and second heat radiation pads are formed of a polymer resin.

10. The thermoelectric module according to claim 7, wherein the polymer resin is formed into a paste for heat radiation, by combining one thermal conductive filler of alumina, silicon nitride (SiNx) and aluminum nitride (AlN) with gelled siloxane polymer.

11. The thermoelectric module according to claim 7, wherein the upper substrate and the lower substrate each have a thickness of 100 μm.

12. The thermoelectric module according to claim 7, wherein the first and second grooves each have a depth of 10 μm.
